(19) United States
(12) Patent Application Publication
(10) Pub. No.: US 2009/0101391 A1
(43) Pub. Date: Apr. 23, 2009

(54) Circuit board having barcode and fabrication method thereof

(75) Inventors: Christina Shu-Ming Yang, Taipei (TW); Feng Hu, Taipei City (TW)

Correspondence Address: Edwards Angell Palmer & Dodge LLP, P. O. Box 55874, Boston, MA, 02205, US

(73) Assignee: Inventec Corporation, Taipei City (TW)

(21) Appl. No.: 11/999,819

(22) Filed: Dec. 6, 2007

(30) Foreign Application Priority Data
Oct. 23, 2007 (TW) 096139602

(51) Int. Cl. H05K 1/00; H05K 3/02

(52) U.S. Cl. 174/250; 29/846

(57) ABSTRACT

A circuit board having barcode and fabrication method thereof are disclosed. The method of the present invention includes the steps of providing a substrate body that has an insulation layer covered with a copper foil; forming a dry film on the copper foil; disposing a film having a circuit pattern and a barcode pattern on the dry film and performing an exposure process so as to harden portions of the dry film at positions corresponding to the circuit pattern and the barcode pattern; performing a development process such that non-hardened portions of the dry film are removed and portions of the dry film that are hardened are remained as an etch mask; and performing an etch process so as to remove portions of the copper foil that are exposed from the dry film. Thus, circuit and barcode are formed in the copper foil at the same time, thereby saving cost and eliminating time for manually attaching barcode.

### BACKGROUND OF THE INVENTION

1. Field of the Invention:

The present invention relates generally to a circuit board and a fabrication method thereof, and more particularly to a circuit board having barcode and a fabrication method thereof.

2. Description of Related Art:

A product barcode is constituted of black and white (or bars and spaces) bars (unit codes) with various widths and corresponding characters for representing certain product information. A barcode can be read by a barcode reader and translated into binary or decimal data identified by computers. The barcode technology develop with the development and application of computer and information technologies, and integrates the techniques including code, print, identification, data capture and process. As barcodes are identified through color contrast between bars and spaces, it requires the color contrast to meet a required PCS value. In general, red, gold and light yellow colors cannot be used as colors representing black color (bars), and transparent or gold color cannot be used as colors representing white color (spaces).

Product barcodes are helpful to control product quality in the manufacturing industry, items having barcodes are easy to be identified and barcodes also facilitate product maintenance and track.

A circuit board having barcode is generally obtained by manually attaching a pre-printed barcode to the finished circuit board. Then, the circuit board can be identified through the barcode and related information such as batch number of the circuit board can be obtained.

In order to save time for printing barcodes and time for manually attaching barcodes to circuit boards, Taiwan Patent No. 81107022 discloses a printed circuit board having barcode and method for forming barcode on a printed circuit board, wherein a barcode is formed on bottom surface of a concave portion of a printed circuit board by spray casting or press casting so as to prevent the barcode from coming off and increase the barcode read reliability.

However, in Taiwan Patent No. 81107022, as the spray casting or press casting is performed while the circuit board is formed by injection molding so as to form a concavo-convex barcode on the circuit board, the fabrication process of the circuit board is rather complicated. Moreover, the barcode color formed by spray casting or press casting is difficult to be read by barcode readers, in other words, such technique cannot achieve a desired identification precision.

Therefore, the conventional method of manually attaching barcodes to circuit boards is not cost-effective as it is time-consuming and requires high labor cost. Meanwhile, the method of forming barcodes on circuit boards by spray casting or press casting while the circuit boards are formed by injection molding is also not cost-effective because the process is rather complicated and the desired identification precision cannot be obtained.

Accordingly, there is a need to provide a circuit board having barcode and fabrication method thereof through which material cost of barcodes and labor cost of manually attaching barcodes to a circuit board can be saved and meanwhile a simplified process of forming barcode on a circuit board can be provided.

### SUMMARY OF THE INVENTION

According to the above drawbacks in the prior art, an objective of the present invention is to provide a circuit board having barcode and a fabrication method thereof so as to save material cost of barcodes and labor cost for manually attaching barcodes to a circuit board.

Another objective of the present invention is to provide a circuit board having barcode and a fabrication method thereof, through which conductive wirings and barcode can be formed on a circuit board at the same time, thereby saving time and cost required by additional processes for forming barcodes.

A further objective of the present invention is to provide a circuit board having barcode and a fabrication method thereof so as to simplify the fabrication process.

In order to attain the above and other objectives, the present invention provides a circuit board having barcode, which comprises: a substrate body having an insulation layer and a conductive wiring disposed on a first surface of the insulation layer; and a metal barcode disposed on a second surface of the insulation layer, and having a plurality of protruding bars spacingly and protrudingly formed on the second surface of the insulation layer, wherein the first surface of the insulation layer is opposing to the second surface of the insulation layer, and the protruding bars form unit codes of the metal barcode.

The present invention further provides a fabrication method of a circuit board having barcode, which comprises the steps of: providing a substrate body having a surface covered with a copper foil; forming a dry film on the copper foil; disposing a film having a wiring pattern and a barcode pattern on the dry film and performing an exposure process so as to harden portions of the dry film at positions corresponding to the wiring pattern and the barcode pattern; performing a development process on the dry film, such that the portions of the dry film corresponding to the wiring pattern and the barcode patter are formed as an etch mask, and removing non-hardened portions of the dry film; and performing an etch process so as to remove portions of the copper foil exposed from the etch mask and removing the etch mask, thereby forming a conductive wiring and a metal barcode at the same time.

The substrate body comprises an insulation layer and copper foil pressed to a surface of the insulation layer. Portions of the dry film corresponding to the wiring pattern and the barcode pattern are hardened through an exposure process. Portions of the dry film not exposed and thus not hardened are named non-hardened portions, and are further removed through a development process using an alkali solution; and the portions of the dry film that correspond to the wiring pattern and the barcode pattern are remained as an etch mask. Then, by performing an etch process using an acidic etching solution, portions of the copper foil exposed from the dry film are removed, thereby forming a conductive wiring and a metal barcode in the copper foil at the same time.

In one embodiment, the insulation layer is made of resin. The metal barcode has a plurality of protruding bars spacingly and protrudingly disposed on surface of the insulation layer, wherein the protruding bars have predetermined widths and are arranged in predetermined positions so as to form unit codes of the metal barcode. Therefore, the present invention can form a conductive wiring and barcode in copper foil on the surface of a substrate body at the same time, which eliminates the need of manually attaching pre-printed barcode or fabricating barcode through spray casting or press casting while a circuit board is formed by injection molding in the prior art, thereby simplifying the fabrication process, saving the fabrication cost and time. The present invention also provides a preferred identification precision.

### BRIEF DESCRIPTION OF DRAWINGS

FIG. 1 is a schematic view showing a circuit board having barcode according to a preferred embodiment of the present invention; and

FIGS. 2A to 2F are schematic views showing a fabrication method of a circuit board having barcode according to a preferred embodiment of the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

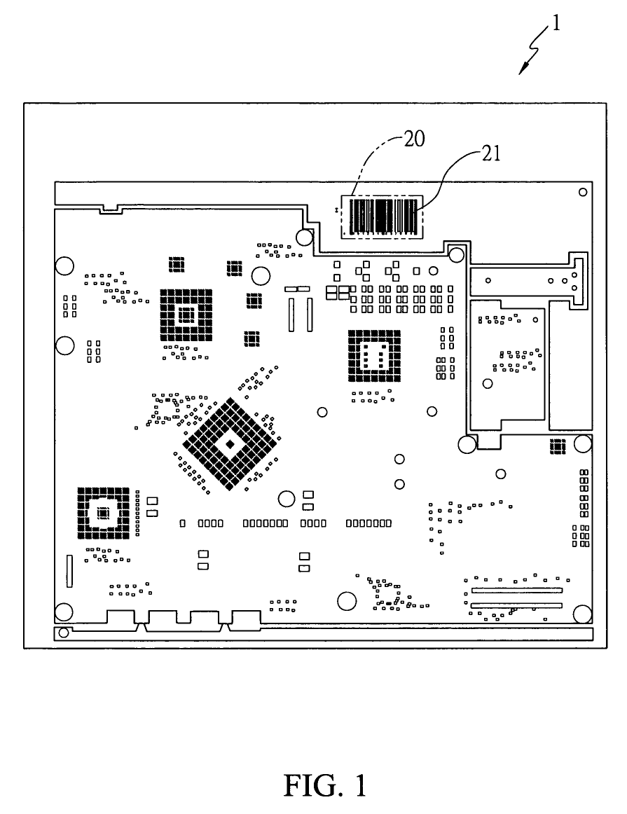

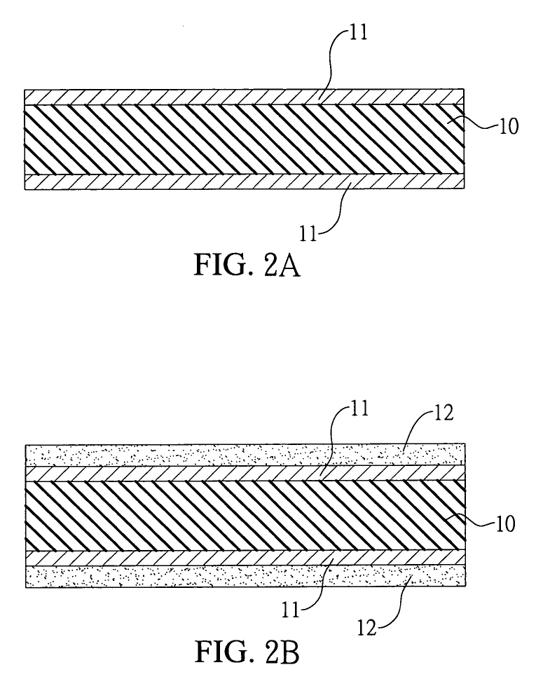

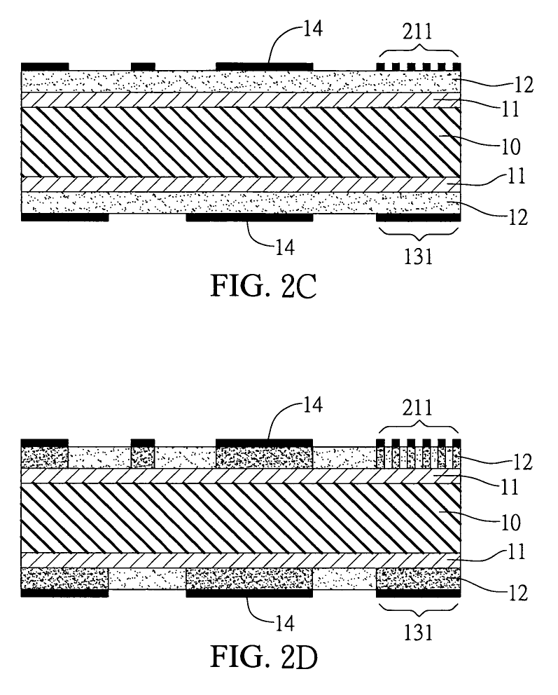

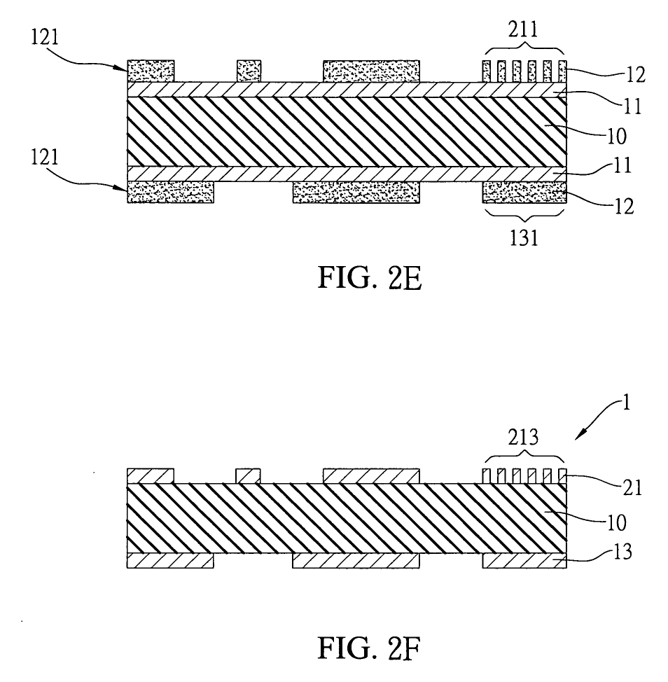

FIG. 1 is a schematic view showing a circuit board having barcode according to a preferred embodiment of the present invention, and FIGS. 2A to 2F are cross-section views showing a fabrication method of a circuit board having barcode in the present invention.

Referring to FIG. 1, a barcode region 20 is defined on the circuit board 1 by the dashed line. The barcode region 20 is disposed on the surface of the insulation layer of the circuit board 1, and a metal barcode 21 is formed in the barcode region 20.

A substrate body having a surface covered with a copper foil is provided, and the substrate body can be a copper clad laminates (CCL) for example. As shown in FIG. 2A, the substrate body includes an insulation layer 10 and a copper foil 11 disposed on surface of the insulation layer 10. In the present embodiment, the copper foil 11 is pressed to the two side surfaces of the insulation layer 10. In other embodiments, the copper foil 11 may be pressed to at least one surface of the insulation layer 10. The insulation layer 10 may be made of resin.

As shown in FIG. 2B, a dry film 12 is formed on the copper foil 11. In the present embodiment, the dry film 12 covers the surface of the copper foil 11, and the dry film 12 can be water-soluble dry film that reacts with alkali to form a water-soluble organic acid salt.

Thereafter, as shown in FIG. 2C, a film 14 having wiring patterns 131 and barcode patterns 211 is disposed on the dry film 12, and exposed. The barcode patterns 211 of the film 14 correspond in position to the barcode region 20 defined on the surface of the substrate body such that the barcode patterns can be formed in the barcode region 20.

As shown in FIG. 2D, through the exposure process, the portions of the dry film 12 corresponding to the wiring patterns 131 and the barcode patterns 211 undergo a polymerization reaction and become hardened.

As shown in FIG. 2E, the film 14 is removed, and then a development process using an alkali solution is performed such that the non-hardened portions of the dry film 12 can be removed, and the portions of the dry film corresponding to the wiring pattern 131 and the barcode pattern 211 can be remained as an etch mask.

Finally, as shown in FIG. 2F, an etch process using an acidic etching solution is performed to remove the portions of the copper foil 11 exposed from the dry film 12, thereby forming conductive wirings 13 and metal barcode 21 in the copper foil 11. Further, the remaining dry film 12 is removed. Referring to FIG. 1, the barcode region 20 is defined at another surface of the insulation layer 10 opposite to the surface of the insulation layer 10 where the conductive wirings 13 disposed.

Through the above fabrication method, a circuit board 1 having barcode as shown in FIG. 2F is obtained. The circuit board 1 includes a substrate body having an insulation layer 10 and a conductive wiring 13 disposed on a first surface of the insulation layer 10; and a metal barcode 21 disposed on a second surface of the insulation layer 10, wherein the first surface of the insulation layer 10 is opposite to the second surface of the insulation layer 10, and wherein the metal barcode 21 has a plurality of protruding bars 213 spacingly and protrudingly disposed on the surface of the insulation layer 10, and the protruding bars 213 have predetermined widths and are arranged in predetermined positions so as to form unit codes of the metal barcode 21. The predetermined widths of the protruding bars 213 correspond to the unit codes. As techniques of using unit codes to represent product information are well known in the prior art, detailed description thereof is omitted.

Thus, the metal barcode 21 is formed on the circuit board 1 and users can identify the metal barcode 21 directly through naked eyes or with the aid of a machine so as to obtain related information of the circuit board 1.

Therefore, compared with the conventional method of manually attaching pre-printed barcodes to finished circuit boards, the present invention saves material cost and labor cost. On the other hand, compared with the conventional method of forming barcodes by spray casting or press casting on circuit boards while the circuit boards are formed by injection molding, the present invention can form conductive circuit and metal barcode in copper foil on surface of circuit boards at the same time, thereby simplifying the fabrication process, and saving the fabrication time and cost.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A circuit board having barcode, comprising:
a substrate body having an insulation layer and a conductive wiring disposed on a first surface of the insulation layer; and
a metal barcode disposed on a second surface of the insulation layer, and having a plurality of protruding bars spacingly and protrudingly formed on the second surface of the insulation layer, wherein the second surface of the insulation layer is opposite to the first surface of the insulation layer, and the protruding bars form unit codes of the metal barcode.

2. The circuit board having barcode of claim 1, wherein the insulation layer is made of resin.

3. The circuit board having barcode of claim 1, wherein the protruding bars have predetermined widths and are arranged in predetermined positions so as to correspond to the unit codes.

4. A fabrication method of a circuit board having barcode, comprising the steps of:
providing a substrate body having a surface covered with a copper foil;
forming a dry film on the copper foil;
disposing a film having a wiring pattern and a barcode pattern on the dry film and performing an exposure process so as to harden portions of the dry film at positions corresponding to the wiring pattern and the barcode pattern;
performing a development process on the dry film, such that the portions of the dry film corresponding to the wiring pattern and the barcode patter are formed as an etch mask, and removing non-hardened portions of the dry film; and
performing an etch process so as to remove portions of the copper foil exposed from the etch mask, and removing the etch mask, thereby concurrently forming a conductive wiring and a metal barcode.

5. The fabrication method of claim 4, further comprising a step of pre-forming an insulation layer on the substrate body; and pressing the copper foil on a surface of the insulation layer.

6. The fabrication method of claim 5, wherein the metal barcode has a plurality of protruding bars spacingly and protrudingly disposed on the surface of the insulation layer, and the protruding bars have predetermined widths and are arranged in predetermined positions, so as to form unit codes of the metal barcode.

7. The fabrication method of claim 4, wherein an alkali solution is used in the development process to remove the non-hardened portions of the dry film, such that the etch mask is formed by the portions of the dry film corresponding to the wiring pattern and the barcode pattern.

8. The fabrication method of claim 4, wherein an acidic etching solution is used in the etch process to remove the portions of the copper foil exposed from the etch mask.
